(19) United States
(12) Patent Application Publication
(10) Pub. No.: US 2004/0067640 A1
(43) Pub. Date: Apr. 8, 2004

(54) Multiple layer copper deposition to improve CMP performance

(75) Inventors: Leon Hsu, Pingtung (TW); Tsu Shih, Hsin-Chu (TW); Chen-Hua Yu, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/266,960

(22) Filed: Oct. 8, 2002

(51) Int. Cl. H01L 21/4763

(52) U.S. Cl. 438/637

(57) ABSTRACT

A method for depositing metal to fill an anisotropically etched feature to improve a subsequent CMP process including a semiconductor wafer including a process surface the process surface further including an anisotropically etched opening lined with a blanket deposited barrier/adhesion layer; blanket depositing metal to form a metal layer filling a portion of the anisotropically etched opening; performing a first chemical mechanical polishing (CMP) process to remove at least a portion of the metal layer comprising a metal overlayer formed over the process surface above the anisotropically etched opening; and, repeating the steps of blanket depositing and performing a first CMP process one or more times to form the metal layer substantially filling the anisotropically etched opening.

### FIELD OF THE INVENTION

This invention generally relates to metal deposition methods for semiconductor manufacturing and more particularly to a method for depositing multiple metal layers such as copper electrodeposition followed by chemical mechanical polishing (CMP) to selectively fill anisotropically etched semiconductor features to improve a CMP process.

### BACKGROUND OF THE INVENTION

Copper and copper alloys have become the metal of choice for filling sub-micron, high aspect ratio interconnect features on semiconductor substrates. Copper and its alloys have lower resistivity and higher electromigration resistance compared to other metals such as, for example, aluminum. These characteristics are critical for achieving higher current densities increased device speed.

As circuit densities increase, the widths of vias, contacts, metal interconnect lines, and other features, decrease to sub-micron dimensions, whereas the thickness of the dielectric layers, through the use low-k (low dielectric constant) materials, has remained substantially constant. Consequently, the aspect ratios for the features, i.e., their height divided by width, has increased thereby creating additional challenges in adequately filling the sub-micron features with, for example, copper metal. Many traditional deposition processes such as chemical vapor deposition (CVD) have difficulty filling increasingly high aspect ratio features, for example, where the aspect ratio exceeds 2:1, and particularly where it exceeds 4:1.

As a result of these process limitations, electroplating or electrodeposition is now a preferable method for filling copper interconnects structures such as via openings and trench line openings on semiconductor devices. Typically, electroplating uses an electrolyte including positively charged ions of deposition material, for example metal ions, in contact with a negatively charged substrate (cathode) having a source of electrons to deposit (plate out) the copper ions by a 2-electron reduction reaction onto the charged substrate, for example, a semiconductor wafer. A barrier/adhesion layer is typically first deposited to line the anisotropically etched features followed by deposition of a thin copper layer (seed layer) to provide a continuous electrical path across the semiconductor wafer surface. An electrical current is supplied to the seed layer whereby the etched features are electroplated with copper to fill the features.

Electro-chemical deposition (ECD) is also used for depositing copper to fill relatively wider area anisotropically etched features such as wide trench lines or bonding pads where feature widths may be from a few microns to several hundred microns in width. Copper chemical mechanical planarization (CMP) is an important aspect of successful ECD processes where excess copper deposited overlying the features is subsequently removed by a CMP planarization process where local and global planarization is critical to successful device operation.

A recurring problem in copper CMP processes is that the simultaneous goals of achieving fast material removal rates of the copper and the underlying barrier/adhesion layer without field oxide (insulating dielectric layer) erosion or copper dishing are difficult to attain. Typically, the excess copper layer is removed following ECD according CMP which generally includes an abrasive polishing slurry and a polishing pad applied with a significant downforce to the semiconductor wafer surface. For example, typically multiple abrasive slurry mixtures are used to achieve the desired selectivity and removal rates. For example, it is frequently desirable to first use a slurry with a high copper removal rate to minimize the required polishing time for relatively thick overlayers of excess copper. The high removal rate slurry is then replaced with a low or medium removal rate slurry and polishing system including a different polishing pad to remove the barrier/adhesion layer at a slower rate to avoid unintended removal of the underlying insulating dielectric layer (erosion) and to minimize copper dishing.

One problem with the approach for using multiple CMP polishing steps, especially in the case of relatively thicker overlayers of copper in relatively wide feature copper areas is the necessity for reliable and accurate endpoint detection. For example, there are a wide variety of endpoint detection systems including optical, chemical, or electrical sensing based systems that are designed to detect the transition from the polishing of one material layer to another. For example, upon detecting the transition from the copper layer to the barrier/adhesion layer, a certain degree of overpolishing is required to ensure substantial removal of the copper layer prior to switching to a barrier/adhesion layer CMP removal process. Frequently, the stability or accuracy of the endpoint detection system may vary depending on the polishing speed and starting non-planarity of the wafer surface. For example, a relatively thicker overlayer of excess copper typically has a higher degree of starting non-planarity and is typically carried out with a high copper removal rate CMP system making accurate endpoint detection together with the appropriate overpolishing difficult to achieve. Since the degree of erosion and dishing is generally proportional to the extent of overpolishing, inaccurate or delayed determination of a polishing endpoint may result in substantial degrees of excessive overpolishing and therefore erosion and dishing. The problem is especially acute for relatively thick and wide copper areas which are more susceptible to copper dishing. In turn, excessive copper dishing will result in electrical device performance degradation and a decreased semiconductor wafer yield.

In addition, with the increasing use of low dielectric constant materials (e.g., <3.5) which typically have a lower strength and poorer adhesion to copper, the shear stresses due to applied polishing loads and platen rotational rates in copper CMP are more likely to cause peeling of the copper layer, especially for thicker overlayers of copper where increased loads and platen rotational rates are typically used to achieve higher copper removal rates.

One approach to reduce the necessity of lengthened copper CMP polishing times has been to electropolish the semiconductor wafer following an electrodeposition process to reduce the thickness of the excess copper layer. This approach creates the difficulty that electropolishing which conformally removes the excess copper does not achieve the desired degree of planarization necessary for subsequent processing steps.

These and other shortcomings demonstrate a need in the semiconductor processing art to develop a method for copper ECD followed by CMP whereby the problems related to accurate endpoint detection and peeling or delamination of copper layers is avoided or reduced thereby increasing a semiconductor wafer yield.

It is therefore an object of the invention to provide a method for metal deposition including copper electrodeposition followed by CMP whereby the problems related to accurate endpoint detection and peeling or delamination of metal including copper layers is avoided or reduced thereby increasing a semiconductor wafer yield while overcoming other shortcomings and deficiencies in the prior art.

### SUMMARY OF THE INVENTION

To achieve the foregoing and other objects, and in accordance with the purposes of the present invention, as embodied and broadly described herein, the present invention provides a method for depositing metal to fill an anisotropically etched feature to improve a subsequent CMP process.

In a first embodiment, the method includes providing a semiconductor wafer including a process surface the process surface further including an anisotropically etched opening lined with a blanket deposited barrier/adhesion layer; blanket depositing metal to form a metal layer filling a portion of the anisotropically etched opening; performing a first chemical mechanical polishing (CMP) process to remove at least a portion of the metal layer comprising a metal overlayer formed over the process surface above the anisotropically etched opening; and, repeating the steps of blanket depositing and performing a first CMP process one or more times to form the metal layer substantially filling the anisotropically etched opening.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1F are cross sectional side view representations of a potion of a multi-layer semiconductor device at stages in manufacture according to the present invention.

FIG. 2 is a process flow diagram including several embodiments of the present invention.

### DETAILED DESCRIPTION OF THE PREFERRED EMBODIMENTS

In the method and apparatus according to the present invention, the invention is explained by reference to electrodeposition (electrochemical deposition) of copper to fill an anisotropically etched feature in a semiconductor wafer, for example a wide area trench or a bonding pad. It will be appreciated, however, that the method of the present invention may be advantageously applied to the blanket deposition of any metal onto a semiconductor surface to fill any anisotropically etched feature where an overlying metal layer formed on the wafer process surface above the feature level is advantageously reduced by multiple metal deposition process cycles including a metal deposition step partially filling the feature followed by a metal CMP process to substantially remove the overlying metal layer above the feature level. It will be appreciated that the term copper as used herein refers to copper and copper alloys.

In one embodiment of the invention, the method includes multiple process cycles including a metal deposition step to blanket deposit metal to partially fill an anisotropically etched feature and a metal CMP step to remove a portion of overlying metal deposited (metal overlayer) on the process surface above the feature level, the metal deposition step and the metal CMP step making up a process cycle that is repeated one or more times to controllably substantially fill the anisotropically etched feature with metal. Following a final process cycle a second CMP process is carried out to remove the metal overlayer and to substantially remove an underlying barrier/adhesion layer.

In another embodiment, the process cycle includes a first metal deposition process to fill a first portion the anisotropically etched opening (feature). Preferably, the first portion includes a deposited metal thickness of between about 25 percent and 50 percent of the feature depth according to blanket deposition. A metal CMP process is then performed to remove a substantial portion of the metal overlayer on the wafer process surface above the feature level. Subsequent process cycles are repeated to substantially fill the anisotropically etched feature with the metal.

By ‘feature level’ is meant the upper level of the anisotropically etched feature formed in an insulating dielectric layer optionally including etching stop or BARC layers formed over the dielectric insulating layer but not including subsequently deposited barrier/adhesion or copper layers. By the term ‘substantial portion’ is meant removal of greater than about 90 percent of the deposited metal overlayer. In one embodiment the metal overlayer is removed to endpoint detection of a transition from a metal polishing surface to a barrier/adhesion layer polishing surface. By the term ‘substantially fill’ is meant that greater than about 90 percent of the depth of the anisotropically etched feature is filled with the deposited metal.

In a preferred embodiment, following the final process cycle a second CMP polishing process is carried out to substantially remove the barrier/adhesion layer underlying the metal overlayer. For example, the second CMP process may include multiple steps, for example, an overpolishing step to substantially remove a remaining portion of the metal overlayer followed by a barrier/adhesion layer CMP polishing process to substantially remove the barrier/adhesion layer, followed by an oxide buffing process to remove remaining scratches from the previous CMP processes including residual material in the scratches. For example in the first CMP process included in the final process cycle following the final metal deposition process, the metal overlayer above the feature level is polished to endpoint detection followed by a second CMP process to substantially remove the underlying barrier/adhesion layer. The second CMP process preferably includes a polishing slurry optimized for barrier/adhesion layer removal, for example, a refractory metal or refractor metal nitride including tantalum, tantalum nitride, titanium and titanium nitride. Optionally, the first and second CMP polishing processes may include multiple polishing platens.

In a preferred embodiment of the present invention the metal deposition process is a copper electrodeposition process. In practicing the method of the present invention, any copper electro-chemical deposition (ECD) process may be used including direct current or alternating current waveforms as is known in the art. In addition, continuous current or pulsed current methods may be used including periodic reverse current processes where electro-polishing of the semiconductor wafer surface occurs. For example, in a preferred electrodeposition process, preferably, at least one reverse current mode (electropolishing) including continuous and pulsed is carried out to electro-polish the deposited copper layer, for example, after depositing about one-half the thickness of a (electroplating) electrodeposition process and following completion of the particular forward current electrodeposition process. For example, periodic reverse current modes following a forward current electrodeposition process reduces the formation of micron sized copper nodules on the electrodeposited copper layer surface thereby reducing micro-scratching in a subsequent CMP process.

In an exemplary embodiment, the method of the present invention is advantageously applied to relatively thick copper fill layers for example, for example from about 1 micron to about 5 microns in thickness. Additionally, features having a width from about 1 micron to about 700 microns advantageously benefit from the method of the present invention. For example, semiconductor wafers having relatively thick semiconductor features will have a correspondingly thick overlayer of copper above the semiconductor feature level. It has been found that relatively thick overlayers of copper, for example, having thicknesses of greater than about 1.0 micron present problems in reliable endpoint detection, for example, resulting in a greater degree of surface non-planarity, frequently resulting in erosion of the insulating dielectric layer and/or dishing of the copper filled feature due to excessive overpolishing over portions of the wafer surface. According to the present invention, the thickness of the electrodeposited copper overlayer above the feature level is kept to a maximum thickness of about 1.3 microns by a multi-step process of electrodeposition followed by a copper CMP process to substantially remove the copper overlayer. It has been found that by limiting the thickness of the electrodeposited copper overlayer above the feature level to less than about 1.3 microns that endpoint detection is more accurate to avoid excessive overpolishing thereby reducing dishing and erosion of the process surface. A further advantage of the present invention is that the incidence of copper layer peeling and delamination is reduced. It is believed that limiting the thickness of the accumulated copper overlayer reduces the magnitude of the shear stress in a CMP process thereby lowering a copper delamination or peeling failure rate.

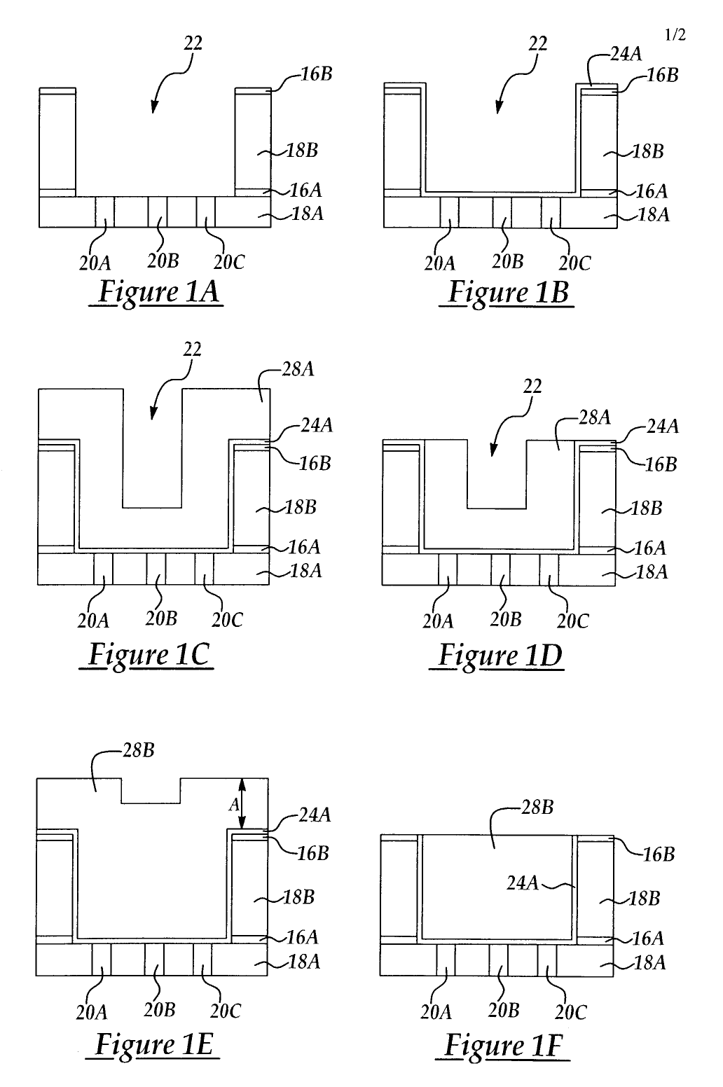

For example, referring to FIGS. 1A-1F, are shown cross-sectional views of a portion of a multi-layer semiconductor device at stages in a manufacturing process according to the present invention. In an exemplary application of the present invention, is shown a cross sectional side view representation of conductive areas e.g., 20A, 20B, and 20C, for example copper filled areas, formed in a dielectric insulating layer 18A including an anisotropically etched opening 22, formed in overlying dielectric insulating layer 18B for example a wide trench or bonding pad opening formed overlying conductive areas, e.g., 20A, 20B, and 20C.

The trench opening 22 is formed by conventional photolithographically patterning and conventional reactive ion etching (RIE) processes to form trench opening 22 in dielectric insulating layer 18B, also referred to as an inter-metal dielectric (IMD) or inter-layer dielectric (ILD) layer. The dielectric insulating layers 18A and 18B are formed of, for example, a low dielectric constant (e.g., less than about 3.5) carbon and/or fluorine doped silicon dioxide layers formed by plasma enhanced CVD (PECVD) to a thickness of about 3000 to about 8000 Angstroms. An etching stop layer 16A is formed overlying conductive regions 20A, 20B, and 20C, typically formed of silicon nitride (e.g., SiN) by known low pressure CVD methods (LPCVD) to a thickness of about 200 Angstroms to about 700 Angstroms. A bottom anti-reflective coating (BARC) layer 16B, for example, formed of silicon oxynitride (e.g., SiON) is formed overlying the IMD layer 18B, typically by an LPCVD process deposited to a thickness of about 800 to about 1400 Angstroms to reduce undesired light reflections in a subsequent photolithographic patterning step to pattern the trench line opening for the reactive ion etching (RIE) process.

Referring to FIG. 1B, following formation of trench line opening 22, a barrier/adhesion layer 24A of a refractory metal or refractory metal nitride, for example, tantalum (Ta), tantalum nitride (e.g., TaN), or titanium nitride (e.g., TiN) nitride, is blanket deposited to include covering the sidewalls and bottom portions of the trench line opening. For example, the tantalum nitride may be deposited by a CVD process or a PVD process first depositing tantalum metal followed by a nitridization process to form tantalum nitride. It will be appreciated that the barrier/adhesion layer 24A may include multiple layers of a refractory metal and/or a refractory metal nitride, for example a dual layer Ti/TiN or Ta/TaN configuration. The barrier/adhesion layer 24A is preferably deposited to a thickness less than about 1000 Angstroms to minimize a contribution to electrical resistivity. The barrier/adhesion layer 24A serves the purpose of preventing copper diffusion into the surrounding IMD layer 18B and improves adhesion of subsequently deposited copper to fill the trench opening. Still referring to FIG. 1B, following deposition of barrier/adhesion layer 24A, a thin copper seed layer (not shown), for example about 50 to about 100 nm is blanket deposited according to a PVD or CVD process to form a continuous conductive layer for providing current in the subsequent electrodeposition process.

Referring to FIG. 1C, according to the present invention first copper layer 28A is deposited by a conventional electrodeposition process to partially fill the trench line opening 22. The electrodeposition process is also frequently referred to as electroplating or electro-chemical deposition (ECD). Preferably, the first copper layer is deposited to about a thickness equal to about ¼ to about ½ of the trench line opening depth. For example, in an electrodeposition process the copper is blanket deposited substantially conformally so that about the same thickness of copper is deposited over the exposed surface including the side walls as shown in FIG. 1C. Although other copper filling methods, such PVD or CVD may be used may be used, electrodeposition is preferred because of its superior gap-filling ability and step coverage. For example, with respect to metal filling layers of aluminum:copper alloys CVD and PVD methods, and combinations thereof as are known in the art may be used for depositing the metal filling layer.

Referring to FIG. 1D, in an exemplary embodiment of the method according to the present invention, a first copper CMP process is carried out to remove at least a portion of the excess copper layer 28A lying above the feature level, (e.g., overlying the barrier/adhesion layer 24A). In one embodiment, the first copper CMP process is carried out to endpoint detection of the barrier/adhesion layer 24A underlying the copper layer 28A. By the term ‘endpoint detection’ is meant that point at which a portion of the underlying barrier/adhesion layer is revealed by the polishing process. Endpoint detection may be accomplished by any process as long as the endpoint detection process detects a point in the CMP process at which a portion of the semiconductor polishing surface includes exposure of a portion of the barrier/adhesion layer 24A underlying copper layer 28A. For example, preferably, at endpoint detection there will be portions of the semiconductor process surface where the barrier/adhesion layer 24A is exposed and portions where the copper layer 28A overlying the barrier/adhesion layer 24A remains. Exemplary endpoint detection systems include, for example, real-time optical detection methods, for example, preferably including wafer polishing surface reflectance measurements, as well as laser interferometry. Preferably, the transition from polishing the copper layer 28A to polishing the adhesion/barrier layer 24A is detected to enable the polishing process to be stopped prior to removal of more than about ¼ to about ½ of the adhesion/barrier layer 24A. Other methods such as polishing pad motor load monitoring, or monitoring the electrical potential of the polishing effluent may be less preferably used for endpoint detection due to increased delay in detecting the transition form polishing the copper layer to polishing the adhesion/barrier layer.

The copper CMP processes included in the first and subsequent process cycles including copper deposition followed by copper CMP according to the present invention are preferably carried out using an abrasive polishing slurry optionally including additives such as oxidizing agents, complexing agents, and corrosion inhibitors for polishing a copper containing semiconductor wafer surface. Suitable oxidizing agents for polishing copper include hydrogen peroxide (H₂O₂) and peroxy containing compounds such as peroxides and percarbonates. Preferably, the abrasive polishing slurry includes abrasive particles including at least one of silica (SiO₂), alumina (Al₂O₃) ceria (CeO₂) , titania (TiO₂) , zirconia (ZrO₂), magnesia (MgO) , and manganese oxide (MnO₂) , or combinations thereof for use as abrasive agents. For example, abrasive particles included in conventional slurries suitably comprise about 5 weight percent to about 30 weight percent of the polishing fluid. Preferably, a conventional rinsing process with deionized water including a spin-spray configuration is carried out following each CMP process prior to an electrodeposition step to ensure removal of slurry and polishing residue prior to carrying out a subsequent electrodeposition process.

Referring to FIG. 1E, following the first process cycle including an electrodeposition process and first copper CMP process, at least a second process cycle including a subsequent electrodeposition and a subsequent first copper CMP process is carried out to substantially fill the trench line opening 22 according to the present invention. For example, a second subsequent copper layer to form a copper layer filling 28B (including copper layer 28A) is electrodeposited to fill a remaining portion of the trench line opening (note that a demarcation line between layer 28A and 28B is not shown). Electrodeposition steps subsequent to a first electrodeposition step incrementally increase the filled copper portion of the feature (e.g., trench line opening 22) including a deposited copper thickness within the feature while minimizing the copper overlayer thickness above the feature level e.g., dimensional indicator A. For example, preferably, the thickness of each of the electrodeposited layers of copper is less than about 1300 nm. Consequently, the copper overlayer above the feature level is likewise preferably limited to less In one embodiment, each of the layers of electrodeposited copper are deposited to about the same thickness. For example, if the first electrodeposited copper layer in the first process cycle is deposited to a thickness of about ½ of the depth of the semiconductor feature, about 2 process cycles will be sufficient to substantially fill the semiconductor feature with copper. It will be appreciated that the electrodeposition and CMP steps to complete a process cycle may be repeated to include more than two process cycles to substantially fill the feature with copper.

Referring to FIG. 1F, in the final process cycle to fill the feature with metal, a single or multiple step CMP process including a first CMP process and a second CMP process is preformed to remove both the overlayer of copper and adhesion/barrier layer 24A above the feature level. For example, the first CMP process includes a copper polishing slurry having a copper removal rate of about 3000 to about 8000 Angstroms per minute and a copper polishing rate with respect to the barrier/adhesion layer polishing rate of greater than about 10:1. For example, the second CMP process includes a barrier/adhesion polishing slurry for polishing, for example, tantalum or tantalum nitride, having a barrier/adhesion layer removal rate of about 100 to about 500 Angstroms per minute with a barrier/adhesion layer polishing rate with respect to a copper polishing rate of about 1:1 to about 3:1. It will be appreciated that additives, for example, copper corrosion inhibitors may be added during the first or second CMP process. Following substantial removal of the copper overlayer, a first overpolishing process to remove a remaining portion of the copper overlayer is optionally performed following endpoint detection, for example, carried for a polishing period of about 5 percent to about 10 percent of the previous copper polishing period. Following substantial removal of the barrier/adhesion layer, an overpolishing process to remove a remaining portion of the barrier/adhesion layer following endpoint detection may optionally be carried out, for example, for a polishing period of about 5 percent to about 10 percent of the previous adhesion/barrier layer polishing period. The second overpolishing process is preferably carried out to ensure removal of the barrier/adhesion layer and copper residue from the polishing surface (process wafer surface). An oxide buffing process following the second overpolishing process is preferably carried out to remove micro-scratches from the polishing surface. In addition, a rinsing process, for example including a spin-spray process is carried out to clean the wafer surface.

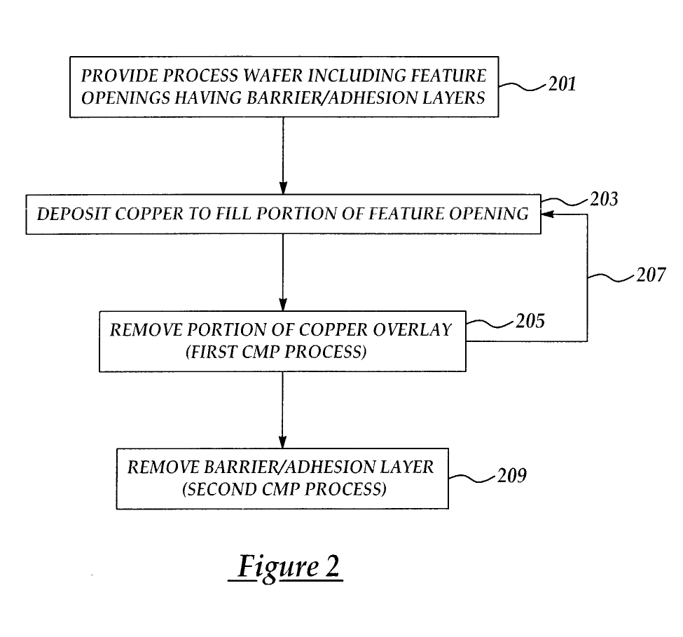

Referring to FIG. 2 is a process flow diagram including several embodiments of the present invention. For example, in process 201, a semiconductor wafer having a process surface including an anisotropically etched feature opening formed in a dielectric insulating layer is provided, the anisotropically etched openings being lined with a blanket deposited barrier/adhesion layer. In process 203 a copper deposition process is carried out to fill a portion of the anisotropically etched feature opening, for example, a copper ECD process including first depositing a copper seed layer over the wafer process surface to form an ECD deposition surface. In process 205 a copper CMP process is performed to remove a portion of an copper overlayer formed above the feature opening level (feature level). The CMP process 205 preferably includes a rinsing step following the CMP process, for example with deionized water to remove residual CMP slurry particles from the wafer surface. Processes 203 and 205 together comprise a process cycle. As indicated by directional arrow 207, the process cycle is repeated one or more times to substantially fill the anisotropically etched features with the deposited metal. In process 209, following the final process cycle including processes 203 and 205, a second CMP process is carried out to substantially remove the barrier/adhesion layer formed above the feature level. In addition, the second CMP process optionally includes an oxide buffing step and a post-CMP rinsing step to complete a metal filled semiconductor feature.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for depositing metal to fill an anisotropically etched feature to improve a subsequent CMP process comprising the steps of:
providing a semiconductor wafer comprising a process surface the process surface further comprising an anisotropically etched opening lined with a blanket deposited barrier/adhesion layer;
blanket depositing metal to form a metal layer filling a portion of the anisotropically etched opening;
performing a first chemical mechanical polishing (CMP) process to remove at least a portion of the metal layer comprising a metal overlayer formed over the process surface above the anisotropically etched opening; and,
repeating the steps of blanket depositing and performing a first CMP process one or more times to form the metal layer substantially filling the anisotropically etched opening.

2. The method of claim 1, further comprising a second CMP process comprising a barrier/adhesion layer CMP process following the step of repeating the steps to substantially remove the barrier/adhesion layer.

3. The method of claim 2 wherein the second CMP process further comprises an overpolishing step to substantially remove residual metal and barrier/adhesion layer material from the process surface and an oxide buffing step following the barrier/adhesion layer CMP process.

4. The method of claim 1, wherein the first CMP process further comprises a rinsing step to remove CMP residual contamination following removal of at least a portion of the metal overlayer.

5. The method of claim 1, wherein the first CMP process comprises at least partially exposing the barrier/adhesion layer.

6. The method of claim 5, wherein the first CMP process comprises endpoint detection means for detecting a polishing layer transition from the metal overlayer to the barrier/adhesion layer.

7. The method of 1, wherein the step of blanket depositing metal to form a metal layer comprises an electro-chemical deposition (ECD) process to form a copper layer.

8. The method of claim 7, wherein the barrier/adhesion layer comprises at least one of a refractory metal and refractory metal nitride.

9. The method of claim 8, wherein the barrier/adhesion layer comprises at least one of tantalum, titanium, and nitrides thereof.

10. The method of claim 9 wherein the first CMP process comprises a material removal rate of between about 3000 Angstroms per minute and about 8000 Angstroms per/minute and the second CMP process comprises a material removal rate of between about 100 Angstrom per minute and about 300 Angstroms per minute.

11. The method of claim 7, wherein the ECD process comprises electropolishing a portion of the copper layer.

12. The method of claim 1, wherein filling a portion comprises forming the metal layer having a thickness equal to about one-fourth to about one-half of the depth of the anisotropically etched opening.

13. A method for blanket depositing copper according to an electro-chemical deposition (ECD) process to fill an anisotropically etched feature to improve a CMP polishing process including endpoint detection and avoiding copper layer delamination comprising the steps of:
providing a semiconductor wafer comprising a process surface the process surface further comprising an anisotropically etched opening lined with a blanket deposited barrier/adhesion layer;
blanket depositing according to an ECD process to form a copper layer filling a portion of the anisotropically etched opening;
performing a first chemical mechanical polishing (CMP) process to remove at least a portion of the copper layer comprising a copper overlayer formed over the process surface above the anisotropically etched opening; and,
repeating the steps of blanket depositing and performing a first CMP process one or more times to form the copper layer substantially filling the anisotropically etched opening.

14. The method of claim 13, further comprising a second CMP process comprising a barrier/adhesion layer CMP process following the step of repeating the steps to substantially remove the barrier/adhesion layer.

15. The method of claim 13, wherein the first CMP process further comprises a rinsing step to remove CMP residual contamination following removal of at least a portion of the copper overlayer.

16. The method of claim 13, wherein the first CMP process comprises at least partially exposing the barrier/adhesion layer.

17. The method of claim 16, wherein the first CMP process comprises an endpoint detection means for detecting a polishing layer transition from the copper overlayer to the barrier/adhesion layer.

18. The method of claim 17, wherein the barrier/adhesion layer comprises at least one of tantalum, titanium, and nitrides thereof.

19. The method of claim 13, wherein the ECD process comprises electropolishing a portion of the copper layer at least following a final step of blanket depositing.

20. The method of claim 13, wherein filling a portion comprises forming the copper layer having a thickness equal to about one-fourth to about one-half of the depth of the anisotropically etched feature opening.
